(19) United States
(12) Patent Application Publication
(10) Pub. No.: US 2025/0377389 A1
(43) Pub. Date: Dec. 11, 2025

(54) MEASURING RANGE EXTENSION FOR CURRENT SENSOR ASSEMBLY

(71) Applicant: MILWAUKEE ELECTRIC TOOL CORPORATION, Brookfield, WI (US)

(72) Inventors: Zhou Lu, Milwaukee, WI (US); Benjamin C. Tesch, Milwaukee, WI (US); Michael A. Matthews, Milwaukee, WI (US)

(21) Appl. No.: 19/230,502

(22) Filed: Jun. 6, 2025

Related U.S. Application Data
(60) Provisional application No. 63/656,748, filed on Jun. 6, 2024.

(51) Int. Cl. G01R 19/10

(52) U.S. Cl. CPC G01R 19/10

(57) ABSTRACT

A current sensing device may include an integrated trace type current sensor assembly. The current sensor assembly may include a chip body, an integrated electrical conductor, and a current sensor. The current sensor measures an amount of first current that flows through the integrated electrical conductor. The current sensing device may also include an external resistive element connected in parallel to the integrated electrical conductor. A second current may flow through the external resistive element. The amount of the first current measured by the current sensor is indicative of a total current that is a sum of the first current and the second current. The total current may be determined based on the amount of the first current measured by the current sensor, based on a first resistance value of the integrated electrical conductor, and based on a second resistance value of the external resistive element.

### RELATED APPLICATIONS

This application claims priority to U.S. Provisional Patent Application No. 63/656,748, filed on Jun. 6, 2024, the entire contents of which are hereby incorporated by reference.

### FIELD

Some disclosed embodiments relate to the use of a current sensor assembly to measure current values of a component of an electronic/electrical device such as a power tool, a power tool battery pack, a portable power source, a bidirectional power converter included in an electronic device, and/or the like.

### SUMMARY

Electronic/electrical devices such as those noted above may include one or more current sensor assemblies to monitor current of one or more components of the electronic devices. Such monitoring of current may allow a control system of each electronic device to make determinations of how to control the electronic device. For example, one or more components of the electronic device may be controlled based on monitored current of one or more other components of the electronic device (e.g., current monitoring during charging or discharging of a battery pack, current monitoring during power conversion in a power converter, overcurrent shutdown, motor control based on current monitoring, etc.).

Current sensor assemblies included in electronic devices may include one of two types: (i) an integrated trace (i.e., internal trace) type current sensor assembly and (ii) an external trace type current sensor assembly. With respect to an integrated trace type current sensor assembly, the current to be measured flows through an electrical conductor integrated into the sensor assembly itself. On the other hand, with respect to an external trace type current sensor assembly, the sensor assembly is designed to be placed adjacent to an external electrical conductor through which the current to be measured flows.

Each of the two above-noted types of current sensor assemblies has advantages and disadvantages that result in a tradeoff when selecting which type of current sensor assembly to use for a given application. Specifically, external trace type current sensor assemblies are more difficult to use/install than integrated trace type current sensor assemblies because they may require additional circuit board design, additional sensor mounting, and additional post-assembly calibration compared to integrated trace type current sensor assemblies. However, as a tradeoff for the additional design and calibration, external trace type current sensor assemblies can be sized to measure larger currents than integrated trace type current sensor assemblies. In other words, external trace type current sensor assemblies generally have a larger current measuring range (e.g., can measure higher currents) than integrated trace type current sensor assemblies.

Some disclosed embodiments relate to extending the measuring range of an integrated trace type current sensor assembly to allow the integrated trace type current sensor assembly to indicate a larger range of measured current values than it would otherwise be capable of measuring. Additional components (e.g., one or more additional external resistors) included in the embodiments disclosed herein allow for higher current measurements to be indicated using an integrated trace type current sensor assembly compared to solely using the integrated trace type current sensor assembly without the additional components disclosed herein. Thus, the systems, methods, and devices disclosed herein maintain the ease-of-use/installation of the integrated trace type current sensor assembly while achieving a larger current measurement range that may otherwise typically only be provided by an external trace type current sensor assembly.

One embodiment provides a current sensing device that may include an integrated trace type current sensor assembly. The integrated trace type current sensor assembly may include a chip body, and an integrated electrical conductor located in or on the chip body. A first current may flow through the integrated electrical conductor. The integrated trace type current sensor assembly may also include a current sensor located in or on the chip body. The current sensor may be configured to measure an amount of the first current. The current sensing device may also include an external resistive element connected in parallel to the integrated electrical conductor. A second current may flow through the external resistive element. A total current that is a sum of the first current and the second current may be determined based on the amount of the first current measured by the current sensor, based on a first resistance value of the integrated electrical conductor, and based on a second resistance value of the external resistive element. A first range of current values that is determinable based on a current measurement from the current sensing device is greater than a second range of current values that is measurable solely by the integrated trace type current sensor assembly without the integrated electrical conductor being connected in parallel to the external resistive element.

In addition to any combination of features described above, the current sensing device may include an electronic processor configured to determine the total current based on the amount of the first current measured by the current sensor, based on the first resistance value of the integrated electrical conductor, and based on the second resistance value of the external resistive element.

In addition to any combination of features described above, the electronic processor may be integrated within the chip body.

In addition to any combination of features described above, the electronic processor may be separate from the integrated trace type current sensor assembly. The electronic processor may receive a measurement signal from the integrated trace type current sensor assembly that indicates the amount of the first current measured by the current sensor.

Another embodiment provides a current sensing device that may include an integrated trace type current sensor assembly. The integrated trace type current sensor assembly may include a chip body, and an integrated electrical conductor located in or on the chip body. A first current may flow through the integrated electrical conductor. The integrated trace type current sensor assembly may also include a current sensor located in or on the chip body. The current sensor may be configured to measure an amount of the first current. The current sensing device may also include an external resistive element connected in parallel to the integrated electrical conductor. A second current may flow through the external resistive element. The amount of the first current measured by the current sensor may be indicative of a total current that is a sum of the first current and the second current.

In addition to any combination of features described above, a first range of current values of the total current that is indicatable by the current sensing device may be greater than a second range of current values of the total current that is indicatable solely by the integrated trace type current sensor assembly (i) without the integrated electrical conductor being connected in parallel to the external resistive element (ii) such that all of the total current passes through the integrated electrical conductor.

In addition to any combination of features described above, the integrated trace type current sensor assembly and the external resistive element may be mounted on a printed circuit board (PCB). A first conductive trace on the PCB may be connected to a first pin of the chip body. The first pin may be connected to a first end of the integrated electrical conductor. The first conductive trace may be connected to a first end of the external resistive element. A second conductive trace on the PCB may be connected to a second pin of the chip body. The second pin may be connected to a second end of the integrated electrical conductor that is opposite to the first end of the integrated electrical conductor. The second conductive trace may be connected to a second end of the external resistive element that is opposite to the first end of the external resistive element.

In addition to any combination of features described above, the current sensing device may include an electronic processor configured to determine the total current based on the amount of the first current measured by the current sensor, based on a first resistance value of the integrated electrical conductor, and based on a second resistance value of the external resistive element.

In addition to any combination of features described above, the electronic processor may be integrated within the chip body.

In addition to any combination of features described above, the electronic processor may be separate from the integrated trace type current sensor assembly. The electronic processor may receive a measurement signal from the integrated trace type current sensor assembly that indicates the amount of the first current measured by the current sensor.

In addition to any combination of features described above, the current sensing device may include a second external resistive element connected in series with the integrated electrical conductor such that the external resistive element is connected in parallel to a series combination of the second external resistive element and the integrated electrical conductor. The first current may flow through the second external resistive element.

In addition to any combination of features described above, the second external resistive element may includes a first tolerance of initial resistance that is smaller than a second tolerance of initial resistance of the integrated electrical conductor, and a first temperature coefficient of resistance that is lower than a second temperature coefficient of resistance of the integrated electrical conductor.

In addition to any combination of features described above, a first accuracy of the current sensing device may be less sensitive to variations in a first resistance value of the integrated electrical conductor than a second accuracy of the current sensing device without the second external resistive element.

In addition to any combination of features described above, the integrated trace type current sensor assembly, the external resistive element, and the second external resistive element may be mounted on a printed circuit board (PCB). A first conductive trace on the PCB may be connected to a first end of the external resistive element and to a first end of the second external resistive element. A second conductive trace on the PCB may be connected between (i) a second end of the second external resistive element that is opposite the first end of the second external resistive element and (ii) a first pin of the chip body. The first pin may be connected to a first end of the integrated electrical conductor. A third conductive trace on the PCB may be connected to a second pin of the chip body. The second pin may be connected to a second end of the integrated electrical conductor that is opposite to the first end of the integrated electrical conductor. The third conductive trace may be connected to a second end of the external resistive element that is opposite to the first end of the external resistive element.

In addition to any combination of features described above, the current sensing device may be implemented within at least one of a group consisting of a power tool battery pack, a power tool, a portable power source, a first bidirectional power converter included in the power tool battery pack, a second bidirectional power converter included in the power tool, a third bidirectional power converter included in the portable power source, and combinations thereof.

Another embodiment provides a current sensing device that may include an integrated trace type current sensor assembly. The integrated trace type current sensor assembly may include a chip body, and an integrated electrical conductor located in or on the chip body. A first current may flow through the integrated electrical conductor. The integrated trace type current sensor assembly may also include a current sensor located in or on the chip body. The current sensor may be configured to measure an amount of the first current. The current sensing device may also include a first external resistive element connected in parallel to the integrated electrical conductor. A second current may flow through the first external resistive element. The current sensing device may include a second external resistive element connected in series with the integrated electrical conductor such that the first external resistive element is connected in parallel to a series combination of the second external resistive element and the integrated electrical conductor. The first current may flow through the second external resistive element. A total current that is a sum of the first current and the second current may be determined based on the amount of the first current measured by the current sensor, based on a first resistance value of the integrated electrical conductor, based on a second resistance value of the first external resistive element, and based on a third resistance value of the second external resistive element.

In addition to any combination of features described above, the second external resistive element may includes a first tolerance of initial resistance that is smaller than a second tolerance of initial resistance of the integrated electrical conductor, and a first temperature coefficient of resistance that is lower than a second temperature coefficient of resistance of the integrated electrical conductor.

In addition to any combination of features described above, a first accuracy of the current sensing device may be less sensitive to variations in a first resistance value of the integrated electrical conductor than a second accuracy of the current sensing device without the second external resistive element.

In addition to any combination of features described above, the integrated trace type current sensor assembly, the first external resistive element, and the second external resistive element may be mounted on a printed circuit board (PCB). A first conductive trace on the PCB may be connected to a first end of the first external resistive element and to a first end of the second external resistive element. A second conductive trace on the PCB may be connected between (i) a second end of the second external resistive element that is opposite the first end of the second external resistive element and (ii) a first pin of the chip body. The first pin may be connected to a first end of the integrated electrical conductor. A third conductive trace on the PCB may be connected to a second pin of the chip body. The second pin may be connected to a second end of the integrated electrical conductor that is opposite to the first end of the integrated electrical conductor. The third conductive trace may be connected to a second end of the first external resistive element that is opposite to the first end of the first external resistive element.

In addition to any combination of features described above, the current sensing device may be implemented within at least one of a group consisting of a power tool battery pack, a power tool, a portable power source, a first bidirectional power converter included in the power tool battery pack, a second bidirectional power converter included in the power tool, a third bidirectional power converter included in the portable power source, and combinations thereof.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 is a simplified block diagram of an electronic/electrical device including a bidirectional power converter in accordance with some example embodiments.

FIG. 2A-2C are perspective views of different electronic devices including the bidirectional power converter of FIG. 1 in accordance with some example embodiments.

FIG. 3 is a simplified block diagram of an inverter bridge of the bidirectional power converter of FIG. 1 in accordance with some example embodiments.

FIG. 4A illustrates a schematic diagram of a current sensing device according to a first example embodiment.

FIG. 4B illustrates a circuit diagram/circuit board layout diagram of the current sensing device of FIG. 4A in accordance with some example embodiments.

FIG. 5A illustrates a schematic diagram of a current sensing device according to a second example embodiment.

FIG. 5B illustrates a circuit diagram/circuit board layout diagram of the current sensing device of FIG. 5A in accordance with some example embodiments.

### DETAILED DESCRIPTION

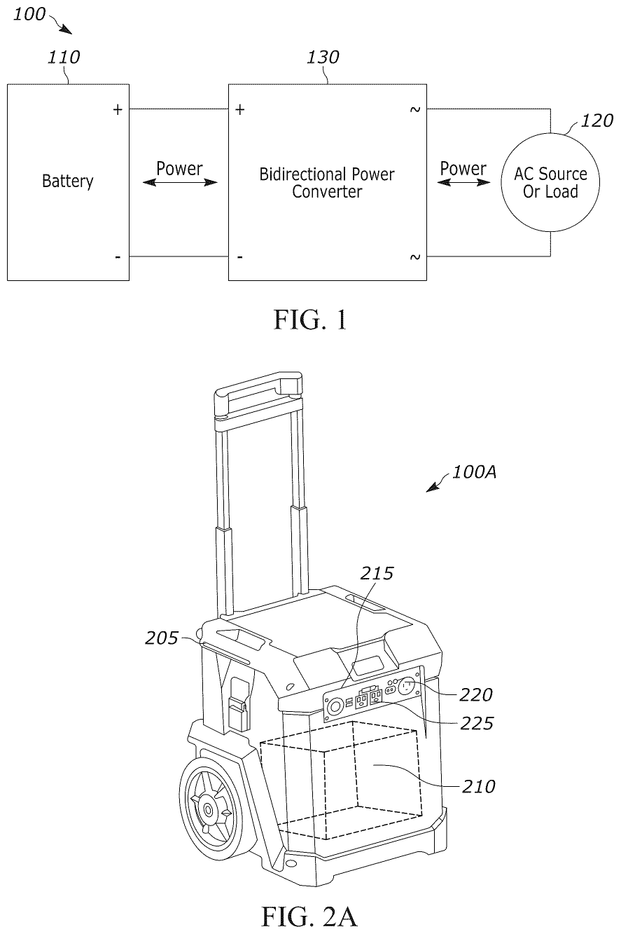

FIG. 1 illustrates a simplified block diagram of an example electronic (i.e., electrical) device 100. The electronic device 100 includes a battery system 110, an alternating current (AC) source or load 120, and a bidirectional power converter 130 electrically connected between the battery system 110 and the AC source or load 120. The bidirectional power converter 130 is configured to convert direct current (DC) to AC and is also configured to convert AC to DC. For example, the bidirectional power converter 130 converts DC power from the battery system 110 to AC power for the load 120 and converts AC power from the AC source 120 to DC power to charge the battery system 110. In some instances, the bidirectional power converter 130 may be used in an electronic device 100 (e.g., a power tool 100C as explained herein) such that current is only converted in one direction (e.g., from the battery system 110 to the load 120) even though the bidirectional power converter 130 may be capable of converting current in the opposite direction.

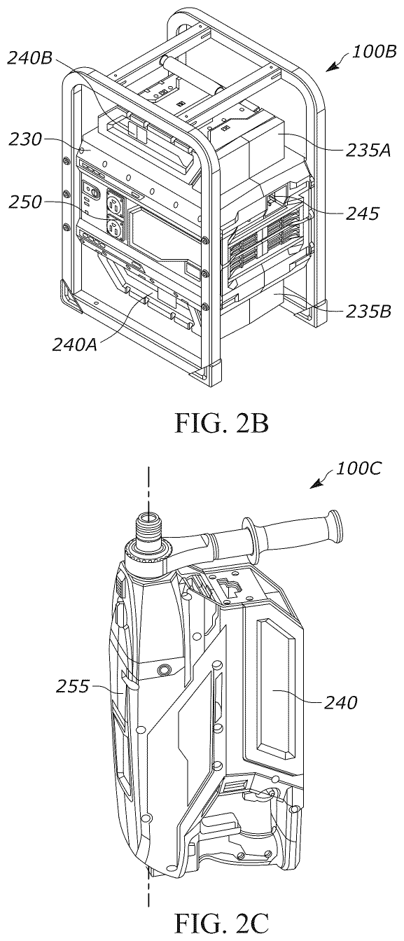

FIG. 2A illustrates an example electronic device 100 in the form of a portable power source/supply 100A. The portable power source 100A includes a housing 205 for housing an internal battery system 210. The housing 205 also includes an input/output panel 215. The input/output panel 215 includes a power input 220 and a power outlet 225. The power outlet 225 is for example, an AC outlet for powering AC electronic devices. The internal battery system 210 corresponds to the battery system 110. In some instances, the internal battery system includes an integrated battery core that is not configured to be removable from the housing 205 by a user. The power input 220 and the power outlet 225 correspond to the AC source 120 or AC load 120, respectively. The bidirectional power converter 130 is coupled between the internal battery system 210, the power input 220, and the power outlet 225. The bidirectional power converter 130 converts DC power from the internal battery system 210 to AC power for the power outlet 225. The bidirectional power converter 130 also converts the AC power from the power input 220 to DC power for charging the internal battery system 210. The portable power source 100A may include additional components other than those described and illustrated herein. For example, the portable power source 100A may include additional power outlets 225 (e.g., both AC and DC), a display, and the like.

FIG. 2B illustrates an example electronic device 100 in the form of another portable power source/supply 100B. The portable power source 100B includes a housing 230 having a first battery interface 235A and a second battery interface 235B. The first battery interface 235A and the second battery interface 235B are configured to respectively receive a first removable power tool battery pack 240A and a second removable power tool battery pack 240B respectively. The first removable power tool battery pack 240A and the second removable power tool battery pack 240B, referred singularly as a removable power tool battery pack 240, are for example, lithium-ion power tool battery packs having a nominal voltage of 12 Volts, 18 Volts, 24 Volts, 36 Volts, 54 Volts, 72 Volts, 90 Volts, 108 Volts, or the like. The removable power tool battery pack 240 may be used to power cordless indoor and outdoor power tools. The portable power source 100B also includes a power input 245 and a power outlet 250. The power outlet 250 is for example, an AC outlet for power AC electronic devices. The removable power tool battery packs 240 correspond to the battery system 110. The power input 245 and the power outlet 250 correspond to the AC source 120 or AC load 120, respectively. The bidirectional power converter 130 is coupled between the removable power tool battery packs 240, the power input 245, and the power outlet 250. The bidirectional power converter 130 converts DC power from the removable power tool battery packs 240 to AC power for the power outlet 250. The bidirectional power converter 130 also converts the AC power from the power input 245 to DC power for charging the removable power tool battery packs 240. The portable power source 100B may include additional components other than those described and illustrated herein. For example, the portable power source 100B may include additional power outlets 250 (e.g., both AC and DC), a display, and the like.

FIG. 2C illustrates an example electronic device 100 in the form of a power tool 100C. In the example illustrated, the power tool 100C is a handheld core drill. The power tool 100C may include a different type of indoor and outdoor, handheld or mounted, power tool, for example, drill/drivers, saws, hammer drills, lighting equipment, grinders, or the like. The power tool 100C includes a housing 255 that houses a motor and that receives a removable power tool battery pack 240. The removable power tool battery pack 240 corresponds to the battery system 110 and the motor corresponds to the AC load 120. The bidirectional power converter 130 is coupled between the removable power tool battery pack 240 and the motor. The bidirectional power converter 130 converts DC power from the removable power tool battery pack 240 to AC power for the motor. In some examples, the power tool 100C may further include a power cord to receive AC power. In these examples, the bidirectional power converter 130 also converts the AC power from the power input or from the motor to DC power for charging the removable power tool battery pack 240. The power tool 100C may include additional components other than those described and illustrated herein.

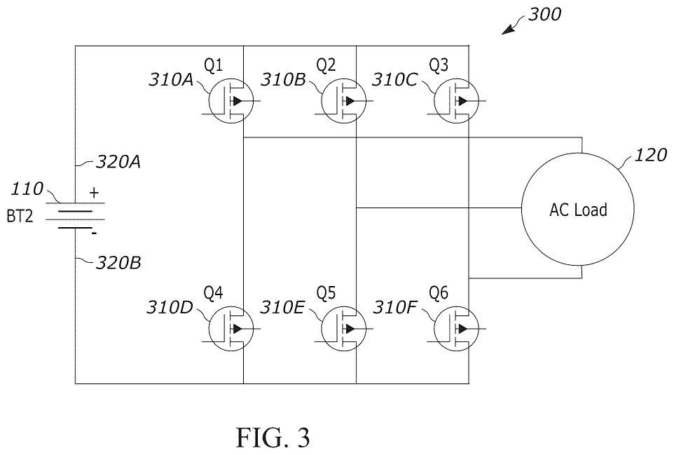

FIG. 3 illustrates a simplified block diagram of an inverter 300 that may be included in the bidirectional power converter 130. In the example illustrated, the inverter 300 includes six switches provided in an inverter bridge configuration. The switches include three high-side switches 310A, 310B, 310C electrically connected between a positive terminal 320A of the battery system 110 and the AC source or load 120. The switches also include three low-side switches 310D, 310E, 310F electrically connected between a negative terminal 320B of the battery system 110 and the AC source or load 120. The plurality of switches 310A-F are controlled by a controller using a gate driver to convert DC power from the battery system 110 to AC power for the AC load 120.

In one example, the plurality of switches 310A-F include metal oxide semiconductor field effect transistors (MOSFETs). In another example, the plurality of switches 310A-F include wide bandgap semiconductor FETs, that is Gallium Nitride (GaN) and/or Silicon Carbide (SiC) based FETs. In yet another example, the plurality of switches 310A-F may include a combination of MOSFETs and wide bandgap semiconductor FETs.

As explained previously herein, electronic devices (such as the electronic devices 100A, 100B, 100C) may include one or more current sensor assemblies to monitor current of one or more components of the electronic devices, for example, to allow a control system of each electronic device to make determinations of how to control the electronic device. Current sensor assemblies may additionally or alternatively be included in a bidirectional power converter 130 that is included in any one or a combination of the electronic devices 100. Also as explained previously herein, some disclosed embodiments relate to extending the measuring range of an integrated trace (i.e., internal trace) type current sensor assembly to allow the integrated trace type current sensor assembly to indicate a larger range of measured current values than it would otherwise be capable of measuring. Thus, the systems, methods, and devices disclosed herein maintain the ease-of-use/installation of the integrated trace type current sensor assembly while achieving a larger current measurement range that may otherwise typically only be provided by an external trace type current sensor assembly.

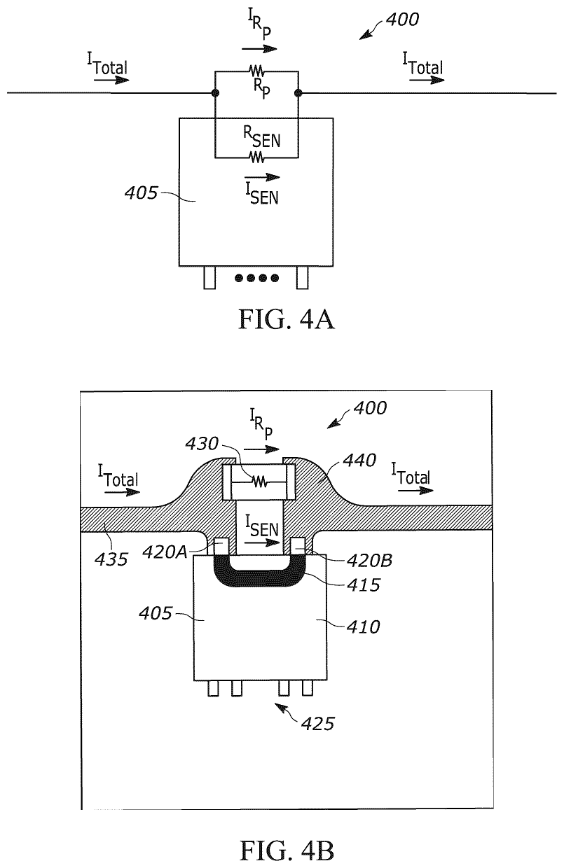

FIG. 4A illustrates a schematic diagram of a current sensing/measuring device 400 according to a first example embodiment. FIG. 4B illustrates a circuit diagram/circuit board layout diagram of the current sensing device 400 of FIG. 4A according to some example embodiments. As shown in FIGS. 4A and 4B, the current sensing device 400 includes an integrated trace type current sensor assembly 405 (as opposed to an external trace type current sensor assembly as described previously herein). The current sensor assembly 405 may include a housing/chip body 410 and an integrated electrical conductor 415 located in or on the chip body 410. The current sensor assembly 405 may also include a current sensor (not shown) located in or on the chip body 410 (e.g., an integrated current sensor). The current sensor may include one or more sensors of the same or different types such as a Hall Effect sensor, a Tunneling Magnetoresistance sensor, a Fluxgate Magnetometer, and/or the like. During operation of the current sensor assembly 405, current flows through the integrated electrical conductor 415 and an amount of current that flows through the integrated electrical conductor 415 is measured by the current sensor. For example, the current sensor assembly 405 may include pins 420A and 420B electrically coupled to the integrated electrical conductor 415 to allow a current to flow through the integrated electrical conductor 415 and be measured by the current sensor of the current sensor assembly 405. The current sensor assembly 405 may also include additional input/output pins 425, for example, to provide a voltage supply to the current sensor, to provide an output signal indicative of the measured current, etc. In some instances, the current sensor assembly 405 is an off-the-shelf integrated circuit (IC) chip that can be installed for use in various applications/electronic devices.

In some instances, the current sensor assembly 405 may only be able to measure up to a current sensor assembly maximum value of current due to limitations (e.g., current limits, temperature limits, etc.) of the components of the current sensor assembly 405. In other words, the current sensor assembly 405 has a limited range of current values that are measurable. However, the use of an external resistive element 430 connected in parallel with the integrated electrical conductor 415 (i.e., connected in parallel with a current measurement path of the current sensor assembly 405) allows the current sensor assembly 405 to output a measured current value that is indicative of a total measured current value that is greater than the current sensor assembly maximum value as explained herein. Thus, the measuring range of the current sensor assembly 405 is effectively extended as explained herein.

In some instances, the external resistive element 430 includes one or more resistive elements in one of various configurations. In the example shown in FIGS. 4A and 4B, the external resistive element 430 includes a single resistor 430 with a resistance R_{P}.

Rather than all of a total current (Iₜₒₜₐₗ) to be measured flowing through integrated electrical conductor 415 of the current sensor assembly 405 as is the case when the current sensor assembly 405 is used without the external resistive element 430, the use of the external resistive element 430 causes the total current to be divided between the external resistive element 430 and the integrated electrical conductor 415 in a manner that is inversely proportional to the resistance of each current path. Accordingly, a first current (I_{SEN}) (i.e., a first portion of the total current) that flows through the integrated electrical conductor 415 is smaller than the total current and is also proportional to the total current. Thus, the current sensor assembly 405 can effectively measure a larger current than its specified input range (i.e., a value larger than the current sensor assembly maximum value). A second current (I_{RP}) (i.e., a second portion of the total current) flows through the external resistive element 430. Since the resistance value (R_{P}) of the external resistive element 430 and the resistance value (R_{SEN}) of the integrated electrical conductor 415 are known, the amount of the first current measured by the current sensor of the current sensor assembly 405 is indicative of the total current that is a sum of the first current and the second current. Equations 1 and 2 below indicate relationships between various current values and resistance values of the current sensing device 400.

$${I}_{Total} = {I}_{SEN} + {I}_{RP} \qquad Equation 1$$

$${I}_{SEN} = \frac{{I}_{Total}}{1 + \frac{{R}_{SEN}}{{R}_{P}}} \qquad Equation 2$$

As indicated by Equation 2 above, the total current can be determined based on the amount of the first current measured by the current sensor of the current sensor assembly 405, based on the first resistance value of the integrated electrical conductor 415, and based on the second resistance value of the external resistive element 430. Specifically, the total current may be determined using Equation 3 below.

$${I}_{Total} = {I}_{SEN} * ( 1 + \frac{{R}_{SEN}}{{R}_{P}} ) \qquad Equation 3$$

In some instances, the current sensor assembly 405 includes an electronic processor (e.g., an electronic processor integrated within the chip body 410) configured to determine the total current based on the amount of the first current measured by the current sensor of the current sensor assembly 405, based on a first resistance value of the integrated electrical conductor, and based on a second resistance value of the external resistive element. In such instances, the current sensor assembly 405 may be programmable or otherwise configured to receive an indication of the resistance value of the external resistive element 430. In other instances, the electronic processor is separate from the integrated trace type current sensor assembly 405 (e.g., as part of a separate controller such as a microcontroller or another IC chip). In such instances, the electronic processor may receive a measurement signal from the integrated trace type current sensor assembly 405 that indicates the amount of the first current measured by the current sensor of the integrated trace type current sensor assembly 405. The electronic processor may use the measured first current value to determine the total current value in accordance with Equation 3 and/or may take an action based on the measured first current value and/or the determined total current value. For example, in response to determining that the measured first current value and/or the determined total current value crosses one or more current threshold values, the electronic processor may control the electronic device 100 in which the current sensing device 400 is located or a component of the electronic device 100 in a certain manner.

As indicated by the above explanation, it is not necessary for the electronic processor to determine the total current value before taking an action. Rather, the measured first current value is, on its own, indicative of the total current even if the total current is not specifically determined/calculated. Accordingly, the current sensing device 400 may be said to have an extended measuring range (e.g., larger measuring range and/or higher maximum value of sensed current) compared to the current sensor assembly 405 on its own (i.e., without the external resistive element 430) even if the total current is not specifically determined.

In some instances, a first range of current values that is determinable based on a current measurement from the current sensing device 400 is greater than a second range of current values that is measurable solely by the integrated trace type current sensor assembly 405 without the integrated electrical conductor 415 being connected in parallel to the external resistive element 430. In some instances, a first range of current values of the total current that is indicatable by the current sensing device 400 is greater than a second range of current values of the total current that is indicatable solely by the integrated trace type current sensor assembly 405 (i) without the integrated electrical conductor 415 being connected in parallel to the external resistive element 430 (ii) such that all of the total current passes through the integrated electrical conductor 415. In some instances, a maximum value of sensed current of the current sensing device 400 is higher than the current sensor assembly maximum value of the current sensor assembly 405 on its own (i.e., without the external resistive element 430).

With reference to FIG. 4B, the current sensing device 400 may be implemented on a printed circuit board (PCB). For example, the integrated trace type current sensor assembly 405 and the external resistive element 430 may be mounted on the PCB. FIG. 4B illustrates a portion a surface of the PCB on which the current sensing device 400 is implemented according to some example embodiments. As shown in FIG. 4B, a first conductive trace 435 on the PCB is connected to a first pin 420A of the chip body 410. The first pin 420A is connected to a first end of the integrated electrical conductor 415. The first conductive trace 435 may also be connected to a first end of the external resistive element 430. A second conductive trace 440 on the PCB is connected to a second pin 420B of the chip body 410. The second pin 420B is connected to a second end of the integrated electrical conductor 415 that is opposite to the first end of the integrated electrical conductor 415. The second conductive trace 440 may also be connected to a second end of the external resistive element 430 that is opposite to the first end of the external resistive element 430.

With the configuration of the current sensing device 400 shown in FIGS. 4A and 4B, the division of current between the external resistive element 430 and the integrated electrical conductor 415 of the current sensor assembly 405 depends upon the resistance (R_{SEN}) of the integrated electrical conductor 415 inside the current sensor assembly 405 because the resistance (R_{SEN}) of the integrated electrical conductor 415 often has a large tolerance of initial resistance and/or a large temperature coefficient of resistance. Comparatively, the external resistive element 430 may have a relatively small tolerance of initial resistance and a relatively small temperature coefficient of resistance. Conductive elements with a larger tolerance of initial resistance and/or a larger temperature coefficient of resistance conduct current less consistently (i.e., have a less consistent resistance value) than conductive elements with a smaller tolerance of initial resistance and/or a smaller temperature coefficient of resistance. Accordingly, the integrated electrical conductor 415 having a large tolerance of initial resistance and/or a large temperature coefficient of resistance can negatively impact the accuracy of the resulting current measurement from the current sensing device 400 assuming that all other values are equal. The negative impact of the accuracy of measured current values is magnified when the resistance (R_{SEN}) of the integrated electrical conductor 415 inside the current sensor assembly 405 is small. For example, Equation 4 below indicates the change in the measured first current (dI_{SEN}) relative to the change in the resistance of the integrated electrical conductor 415 inside the current sensor assembly 405 (dR_{SEN}). Since lower values of R_{SEN} decrease the value of the denominator in Equation 4, changes in R_{SEN} at these lower values result in larger changes to the measured first current (I_{SEN}).

$$\frac{{dI}_{SEN}}{{dR}_{SEN}} = - \frac{{I}_{Total}}{{R}_{P} + 2 \cdot {R}_{SEN} + \frac{{R}_{{SEN}^{2}}}{{R}_{P}}} \qquad Equation 4$$

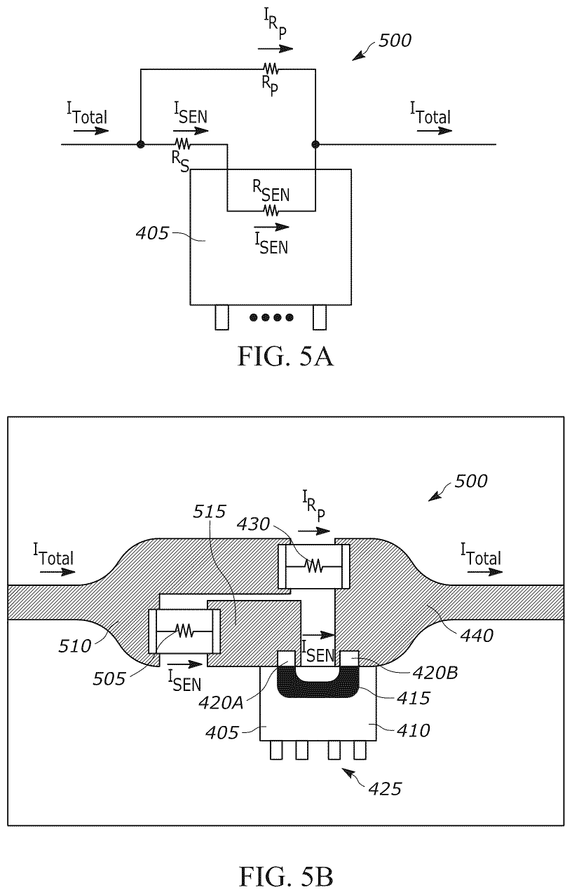

To mitigate the negative impacts that the resistance (R_{SEN}) of the integrated electrical conductor 415 inside the current sensor assembly 405 may have on the accuracy of measurements of the first current, an additional external resistive element 505 may be used as shown in FIGS. 5A and 5B and as explained below.

FIG. 5A illustrates a schematic diagram of a current sensing device 500 according to a second example embodiment. FIG. 5B illustrates a circuit diagram/circuit board layout diagram of the current sensing device 500 of FIG. 5A according to some example embodiments. Many of the components of the current sensing device 500 are the same as or similar to the like-named components of the current sensing device 400. For the sake of brevity, these like-named components will not be explained in detail again but the above explanation of these components and related components (e.g., the electronic processor) with respect to the current sensing device 400 applies to the like-named components of the current sensing device 500.

As shown in FIGS. 5A and 5B, the current sensing device 500 is similar to the current sensing device 400 of FIGS. 4A and 4B but, in addition to a first external resistive element 430, the current sensing device 500 includes a second external resistive element 505 connected in series with the integrated electrical conductor 415 such that the first external resistive element 430 is connected in parallel to a series combination of the second external resistive element 505 and the integrated electrical conductor 415. The first current (I_{SEN}) to be measured by the current sensor of the current sensor assembly 405 flows through the second external resistive element 505 and the integrated electrical conductor 415.

In some instances, the second external resistive element 505 includes one or more resistive elements in one of various configurations. In the example shown in FIGS. 5A and 5B, the second external resistive element 505 includes a single resistor 505 with a resistance R_{S}.

In some instances, characteristics of resistance of the second external resistive element 505 (and the first external resistive element 430) are selected to be better than those of the integrated electrical conductor 415. For example, the second external resistive element 505 includes a first tolerance of initial resistance that is smaller/tighter than a second tolerance of initial resistance of the integrated electrical conductor 415. The second external resistive element 505 may additionally or alternatively include a first temperature coefficient of resistance that is lower than a second temperature coefficient of resistance of the integrated electrical conductor 415. With the characteristics of resistance of the second external resistive element 505 chosen in this manner, the accuracy of the current sensing device 500 is less sensitive to variations in the resistance (R_{SEN}) of the integrated electrical conductor 415 due to initial tolerance or temperature than when the second external resistive element 505 is not used, assuming all other values are equal. For example, Equation 5 below indicates the change in the measured first current (dI_{SEN}) relative to the change in the resistance of the integrated electrical conductor 415 inside the current sensor assembly 405 (dR_{SEN}). Compared to Equation 4 that represents the current sensing device 400 without the second external resistive element 505, the denominator of Equation 5 is made larger because the resistance of the second external resistive element (R_{S}) is positive, which results in smaller changes to the measured first current (I_{SEN}) due to changes in R_{SEN} than for the current sensing device 400 without the second external resistive element 505.

$$\frac{{dI}_{SEN}}{{dR}_{SEN}} = - \frac{{I}_{Total}}{{R}_{P} + 2 \cdot ( {R}_{S} + {R}_{SEN} ) + \frac{{( {R}_{S} + {R}_{SEN} )}^{2}}{{R}_{P}}} \qquad Equation 5$$

Additionally, because the overall resistance of the external resistive elements 430 and 505 and of the integrated electrical conductor 415 in the current sensing device 500 is greater than the overall resistance of the external resistive element 430 and of the integrated electrical conductor 415 in the current sensing device 400 (assuming all other values are equal), the current measurement accuracy impact due to variation in the resistance of any conductors in the current sensing device 500 (e.g., the integrated electrical conductor 415, conductive traces 440, 510, and 515 of the PCB that tend to have a large temperature coefficient of resistance, and/or the like) is also reduced.

As indicated by the above explanations, a first accuracy of the current sensing device 500 (with the second external resistive element 505) is less sensitive to variations in a first resistance value of the integrated electrical conductor 415 than a second accuracy of the current sensing device 400 without the second external resistive element 505.

Similar to the current sensing device 400, during operation of the current sensing device 500, the total current is divided between (i) the first external resistive element 430 and (ii) a series combination of the second external resistive element 505 and the integrated electrical conductor 415 in a manner that is inversely proportional to the resistance of each current path. Accordingly, a first current (I_{SEN}) (i.e., a first portion of the total current) that flows through the second external resistive element 505 and the integrated electrical conductor 415 is smaller than the total current and is also proportional to the total current. Thus, the current sensor assembly 405 can effectively measure a larger current than its specified input range (i.e., a current sensor assembly maximum value). A second current (I_{RP}) (i.e., a second portion of the total current) flows through the external resistive element 430. Since the resistance value (R_{P}) of the first external resistive element 430, the resistance value (R_{S}) of the second external resistive element 505, and the resistance value (R_{SEN}) of the of the integrated electrical conductor 415 are known, the amount of the first current measured by the current sensor of the current sensor assembly 405 is indicative of the total current that is a sum of the first current and the second current. Equations 6 and 7 below indicate relationships between various current values and resistance values of the current sensing device 500.

$${I}_{Total} = {I}_{SEN} + {I}_{{R}_{P}} \qquad Equation 6$$

$${I}_{SEN} = \frac{{I}_{Total}}{1 + \frac{{R}_{S} + {R}_{SEN}}{{R}_{P}}} \qquad Equation 7$$

As indicated by Equation 7 above, the total current can be determined based on the amount of the first current measured by the current sensor of the current sensor assembly 405, based on the first resistance value of the integrated electrical conductor 415, based on the second resistance value of the first external resistive element 430, and based on the third resistance value of the second external resistive element 505. Specifically, the total current may be determined using Equation 8 below.

$${I}_{Total} = {I}_{SEN} * ( 1 + \frac{{R}_{S} + {R}_{SEN}}{{R}_{P}} ) \qquad Equation 8$$

With reference to FIG. 5B and similar to the current sensing device 400, the current sensing device 500 may be implemented on a PCB. For example, the integrated trace type current sensor assembly 405, the first external resistive element 430, and the second external resistive element 505 are mounted on the PCB. FIG. 5B illustrates a portion a surface of the PCB on which the current sensing device 500 is implemented according to some example embodiments. As shown in FIG. 5B, a first conductive trace 510 on the PCB is connected to a first end of the first external resistive element 430 and to a first end of the second external resistive element 505. A second conductive trace 515 on the PCB may be connected between (i) a second end of the second external resistive element 505 that is opposite the first end of the second external resistive element 505 and (ii) a first pin 420A of the chip body 410. The first pin 420A is connected to a first end of the integrated electrical conductor 415. A third conductive trace 440 on the PCB is connected to a second pin 420B of the chip body 410. The second pin 420B is connected to a second end of the integrated electrical conductor 415 that is opposite to the first end of the integrated electrical conductor 415. The third conductive trace is also connected to a second end of the first external resistive element 430 that is opposite to the first end of the first external resistive element 430.

Other electrical connections besides conductive traces on a PCB may be used to connect the circuit elements disclosed herein. In some instances, the components of the current sensing devices 400, 500 may be arranged differently to achieve the same or a similar outcome. For example, the second external resistive element 505 may be arranged in series with the integrated electrical conductor 415 between the second pin 420B and an electrical conductor instead of being connected between the first pin 420A and an electrical conductor (i.e., the conductive trace 440 is modified to be two separate traces and the conductive traces 505 and 510 are modified to be a single conductive trace).

Similar to the current sensing device 400 described above, the current sensing device 500 may be implemented within at least one of a group consisting of a power tool battery pack, a power tool, a portable power source, a first bidirectional power converter included in the power tool battery pack, a second bidirectional power converter included in the power tool, a third bidirectional power converter included in the portable power source, and combinations thereof.

Although the disclosure has been described in detail with reference to certain preferred embodiments, variations and modifications exist within the scope and spirit of one or more independent aspects of the disclosure as described. Various features and advantages are set forth in the following claims.

What is claimed is:

1. A current sensing device comprising:
an integrated trace type current sensor assembly including
a chip body,
an integrated electrical conductor located in or on the chip body, wherein a first current flows through the integrated electrical conductor, and
a current sensor located in or on the chip body, wherein the current sensor is configured to measure an amount of the first current; and
an external resistive element connected in parallel to the integrated electrical conductor, wherein a second current flows through the external resistive element;
wherein a total current that is a sum of the first current and the second current is determined based on the amount of the first current measured by the current sensor, based on a first resistance value of the integrated electrical conductor, and based on a second resistance value of the external resistive element; and
wherein a first range of current values that is determinable based on a current measurement from the current sensing device is greater than a second range of current values that is measurable solely by the integrated trace type current sensor assembly without the integrated electrical conductor being connected in parallel to the external resistive element.

2. The current sensing device of claim 1, further comprising an electronic processor configured to determine the total current based on the amount of the first current measured by the current sensor, based on the first resistance value of the integrated electrical conductor, and based on the second resistance value of the external resistive element.

3. The current sensing device of claim 2, wherein the electronic processor is integrated within the chip body.

4. The current sensing device of claim 2, wherein the electronic processor is separate from the integrated trace type current sensor assembly, and wherein the electronic processor receives a measurement signal from the integrated trace type current sensor assembly that indicates the amount of the first current measured by the current sensor.

5. A current sensing device comprising:
an integrated trace type current sensor assembly including
a chip body,
an integrated electrical conductor located in or on the chip body, wherein a first current flows through the integrated electrical conductor, and
a current sensor located in or on the chip body, wherein the current sensor is configured to measure an amount of the first current; and
an external resistive element connected in parallel to the integrated electrical conductor, wherein a second current flows through the external resistive element;
wherein the amount of the first current measured by the current sensor is indicative of a total current that is a sum of the first current and the second current.

6. The current sensing device of claim 5, wherein a first range of current values of the total current that is indicatable by the current sensing device is greater than a second range of current values of the total current that is indicatable solely by the integrated trace type current sensor assembly (i) without the integrated electrical conductor being connected in parallel to the external resistive element (ii) such that all of the total current passes through the integrated electrical conductor.

7. The current sensing device of claim 5, wherein the integrated trace type current sensor assembly and the external resistive element are mounted on a printed circuit board (PCB);
wherein a first conductive trace on the PCB is connected to a first pin of the chip body, and wherein the first pin is connected to a first end of the integrated electrical conductor;
wherein the first conductive trace is connected to a first end of the external resistive element;
wherein a second conductive trace on the PCB is connected to a second pin of the chip body, and wherein the second pin is connected to a second end of the integrated electrical conductor that is opposite to the first end of the integrated electrical conductor; and
wherein the second conductive trace is connected to a second end of the external resistive element that is opposite to the first end of the external resistive element.

8. The current sensing device of claim 5, further comprising an electronic processor configured to determine the total current based on the amount of the first current measured by the current sensor, based on a first resistance value of the integrated electrical conductor, and based on a second resistance value of the external resistive element.

9. The current sensing device of claim 8, wherein the electronic processor is integrated within the chip body.

10. The current sensing device of claim 8, wherein the electronic processor is separate from the integrated trace type current sensor assembly, and wherein the electronic processor receives a measurement signal from the integrated trace type current sensor assembly that indicates the amount of the first current measured by the current sensor.

11. The current sensing device of claim 5, further comprising a second external resistive element connected in series with the integrated electrical conductor such that the external resistive element is connected in parallel to a series combination of the second external resistive element and the integrated electrical conductor, wherein the first current flows through the second external resistive element.

12. The current sensing device of claim 11, wherein the second external resistive element includes:
a first tolerance of initial resistance that is smaller than a second tolerance of initial resistance of the integrated electrical conductor; and
a first temperature coefficient of resistance that is lower than a second temperature coefficient of resistance of the integrated electrical conductor.

13. The current sensing device of claim 11, wherein a first accuracy of the current sensing device is less sensitive to variations in a first resistance value of the integrated electrical conductor than a second accuracy of the current sensing device without the second external resistive element.

14. The current sensing device of claim 11, wherein the integrated trace type current sensor assembly, the external resistive element, and the second external resistive element are mounted on a printed circuit board (PCB);
wherein a first conductive trace on the PCB is connected to a first end of the external resistive element and to a first end of the second external resistive element;
wherein a second conductive trace on the PCB is connected between (i) a second end of the second external resistive element that is opposite the first end of the second external resistive element and (ii) a first pin of the chip body, wherein the first pin is connected to a first end of the integrated electrical conductor;
wherein a third conductive trace on the PCB is connected to a second pin of the chip body, and wherein the second pin is connected to a second end of the integrated electrical conductor that is opposite to the first end of the integrated electrical conductor; and
wherein the third conductive trace is connected to a second end of the external resistive element that is opposite to the first end of the external resistive element.

15. The current sensing device of claim 5, wherein the current sensing device is implemented within at least one of a group consisting of a power tool battery pack, a power tool, a portable power source, a first bidirectional power converter included in the power tool battery pack, a second bidirectional power converter included in the power tool, a third bidirectional power converter included in the portable power source, and combinations thereof.

16. A current sensing device comprising:
an integrated trace type current sensor assembly including
a chip body,
an integrated electrical conductor located in or on the chip body, wherein a first current flows through the integrated electrical conductor, and
a current sensor located in or on the chip body, wherein the current sensor is configured to measure an amount of the first current;
a first external resistive element connected in parallel to the integrated electrical conductor, wherein a second current flows through the first external resistive element; and
a second external resistive element connected in series with the integrated electrical conductor such that the first external resistive element is connected in parallel to a series combination of the second external resistive element and the integrated electrical conductor, wherein the first current flows through the second external resistive element;
wherein a total current that is a sum of the first current and the second current is determined based on the amount of the first current measured by the current sensor, based on a first resistance value of the integrated electrical conductor, based on a second resistance value of the first external resistive element, and based on a third resistance value of the second external resistive element.

17. The current sensing device of claim 16, wherein the second external resistive element includes:
a first tolerance of initial resistance that is smaller than a second tolerance of initial resistance of the integrated electrical conductor; and
a first temperature coefficient of resistance that is lower than a second temperature coefficient of resistance of the integrated electrical conductor.

18. The current sensing device of claim 16, wherein a first accuracy of the current sensing device is less sensitive to variations in a first resistance value of the integrated electrical conductor than a second accuracy of the current sensing device without the second external resistive element.

19. The current sensing device of claim 16, wherein the integrated trace type current sensor assembly, the first external resistive element, and the second external resistive element are mounted on a printed circuit board (PCB);
wherein a first conductive trace on the PCB is connected to a first end of the first external resistive element and to a first end of the second external resistive element;
wherein a second conductive trace on the PCB is connected between (i) a second end of the second external resistive element that is opposite the first end of the second external resistive element and (ii) a first pin of the chip body, wherein the first pin is connected to a first end of the integrated electrical conductor;
wherein a third conductive trace on the PCB is connected to a second pin of the chip body, and wherein the second pin is connected to a second end of the integrated electrical conductor that is opposite to the first end of the integrated electrical conductor; and
wherein the third conductive trace is connected to a second end of the first external resistive element that is opposite to the first end of the first external resistive element.

20. The current sensing device of claim 16, wherein the current sensing device is implemented within at least one of a group consisting of a power tool battery pack, a power tool, a portable power source, a first bidirectional power converter included in the power tool battery pack, a second bidirectional power converter included in the power tool, a third bidirectional power converter included in the portable power source, and combinations thereof.
